(19) United States
(12) Patent Application Publication
(10) Pub. No.: US 2014/0048320 A1
(43) Pub. Date: Feb. 20, 2014

(54) PRINTED CIRCUIT BOARD AND METHOD FOR MANUFACTURING THE SAME

(71) Applicant: SAMSUNG ELECTRO-MECHANICS CO., LTD., Gyunggi-do (KR)

(72) Inventors: Yong Jin Park, Gyunggi-do (KR); Yong Gwan Ko, Gyunggi-do (KR); Hye Won Jung, Gyunggi-do (KR); Joon Sung Kim, Gyunggi-do (KR)

(73) Assignee: Samsung Electro-Mechanics Co., Ltd., Gyunggi-do (KR)

(21) Appl. No.: 13/708,802

(22) Filed: Dec. 7, 2012

(30) Foreign Application Priority Data
Aug. 20, 2012 (KR) 10-2012-0090669

(51) Int. Cl. H05K 1/03; H05K 3/10; H05K 1/00

(52) U.S. Cl. CPC H05K 1/03; H05K 1/00; H05K 3/10
USPC 174/259; 174/250; 427/97.3; 427/96.8

(57) ABSTRACT

Disclosed herein are a printed circuit board and a method for manufacturing the same, the printed circuit board including an adhesion promoter (AP) film for enhancing adhesive strength, interposed between a circuit pattern and an insulating layer above a substrate, the AP film containing any one of a first polymer, a second polymer, and an organic compound. According to the method for manufacturing the printed circuit board, there can be provided a printed circuit board having a fine circuit pattern by using the AP film having a low roughness value and having improved adhesive strength with respect to the circuit pattern.

### CROSS REFERENCE TO RELATED APPLICATION

This application claims the benefit of Korean Patent Application No. 10-2012-0090669, filed on Aug. 20, 2012, entitled “Printed Circuit Board and Method for Manufacturing the Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

In general, a printed circuit board is manufactured by forming wirings on one surface or both surfaces of a board made of various heat-hardenable synthetic resins using a copper foil, fixedly disposing integrated circuits (ICs) or electronic components on the board, implementing electrical wirings between the ICs or the electronic components, then coating the electrical wirings using an insulator.

In accordance with the recent development of electronic industry, the demand for multi-functional and slim and light electronic components has rapidly increased. Therefore, a printed circuit board having these electronic components mounted thereon has also been required to have high density wirings and a thin thickness.

Particularly, in an additive method or a semi-additive process (SAP) method for manufacturing the printed circuit board, an adhesive strength between a resin and a plating layer is secured by performing a desmear treatment on an insulating layer formed of the resin to thereby increase the roughness thereof, followed by plating, or by performing a roughening treatment on a copper circuit, followed by coating the resin thereon.

However, in the printed circuit board manufactured by the above method, fine circuits may be difficult to form due to high roughness and there may be a large loss in signal transmission.

A board having low roughness is attempted to be manufactured in order to overcome the above disadvantages, but this board has a deteriorated adhesive strength between a resin and a circuit due to low roughness and bad reliability as a printed circuit board.

In order to overcome the above disadvantages, Korean Patent Laid-Open Publication No. 2010-0050422 (May 13, 2010) discloses that a high adhesive strength is secured with low roughness by using an adhesive liquid, a tin plating liquid, or the like.

However, since these methods employ a wet process using the adhesive liquid, tin plating liquid, or the like, the treatment cost is high and periodic management of the solution is needed.

### SUMMARY OF THE INVENTION

The present invention has been made in an effort to provide a printed circuit board easily including an adhesion promoter (AP) film for improving adhesive strength between a circuit pattern and an insulating material.

Further, the present invention has been made in an effort to provide a method for manufacturing a printed circuit board having low roughness and high interlayer adhesive strength by easily including an adhesion promoter (AP) film for improving adhesive strength between a circuit pattern and an insulating material.

According to one preferred embodiment of the present invention, there is provided a printed circuit board comprising an adhesion promoter (AP) film for enhancing adhesive strength, interposed between a circuit pattern and an insulating layer above a substrate.

The AP film may contain a first polymer and an organic compound, and the insulating layer may include a solder resist (SR) layer.

The AP film may further contain a second polymer.

The first polymer may include any one or at least two polymers of amine based polymers, imidazole based polymers, and pyridine based polymers.

The second polymer may include a heat hardenable synthetic resin.

The organic compound may include any one or at least two compounds of aromatic compounds, and the aromatic compounds may include divinyl benzene, styrene, and ethylvinyl benzene.

The AP film may be formed by attaching the first polymer onto the circuit pattern and attaching the second polymer and the organic compound onto the insulating layer, by using any one of chemical vapor deposition (CVD), initiated chemical vapor deposition (iCVD), and spin coating methods.

According to another preferred embodiment of the present invention, there is provided a method for manufacturing a printed circuit board, the method including forming an AP film for enhancing adhesive strength to be interposed between a circuit pattern and an insulating layer above a substrate.

The forming of the AP film may include: forming the insulating layer above the substrate; forming the circuit pattern on the insulating layer; forming the AP film on an insulating layer having the circuit pattern formed thereon; and forming a different insulating layer on the AP film.

The forming of the AP film may include: forming the insulating layer above the substrate; forming the AP film on the insulating layer; forming a copper plating layer on the AP film; and performing a patterning process for forming the copper plating layer into a circuit pattern.

The AP film may be formed as a film containing at least one of a first polymer, a second polymer, and an organic compound, by using any one of chemical vapor deposition (CVD), initiated chemical vapor deposition (iCVD), and spin coating methods.

The first polymer may be attached onto the circuit pattern and the second polymer and the organic compound may be attached onto the insulating layer.

The first polymer may include any one or at least two polymers of amine based polymers, imidazole based polymers, and pyridine based polymers; the second polymer may include a heat hardenable synthetic resin; and the organic compound may include any one or at least two compounds of aromatic compounds.

The aromatic compounds may include divinyl benzene, styrene, and ethylvinyl benzene.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is an exemplified view for illustrating a process of forming an AP film according to the present invention;

FIGS. 2A to 2C are process cross-sectional views for illustrating a method for manufacturing a printed circuit board including an AP film according to a first preferred embodiment of the present invention;

FIGS. 3A to 3C are process cross-sectional views for illustrating a method for manufacturing a printed circuit board including an AP film according to a second preferred embodiment of the present invention; and

FIGS. 4A to 4C are process cross-sectional views for illustrating a method for manufacturing a printed circuit board including an AP film according to a third preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

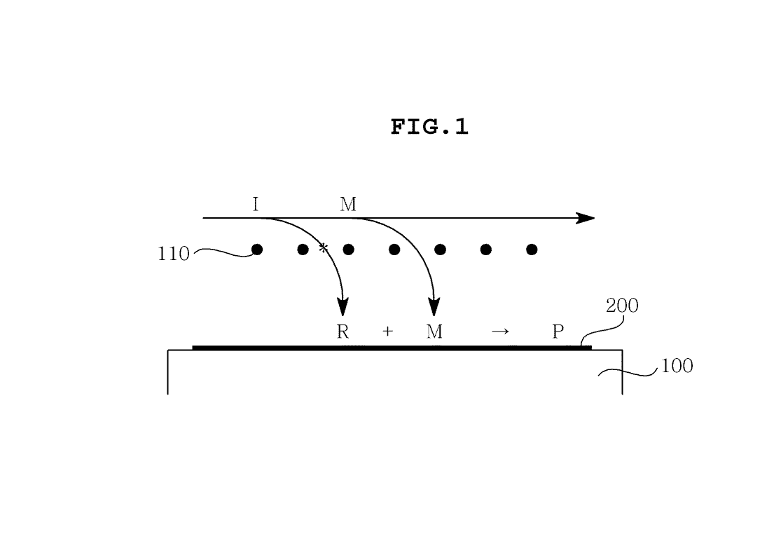

Hereinafter, preferred embodiments of the present invention will be described in detail with reference to the accompanying drawings. FIG. 1 is an exemplified view for illustrating a process of forming an AP film according to the present invention.

An adhesion promoter (AP) film according to the present invention is interposed in a structure requiring adhesive strength for an interface between heterogeneous layers, such as, between a circuit pattern and an insulating layer, between a circuit pattern and a solder resist (SR), or the like, to thereby enhance the adhesive strength for the circuit pattern, the insulating layer, or the SR even without a roughening treatment process.

This adhesion promoter (AP) film may be formed while containing a first polymer and an organic compound, and optionally a second polymer.

Specifically, examples of the first polymer may include amine based polymers, imidazole based polymers, pyridine based polymers, and the like; examples of the second polymer may include heat-hardenable synthetic resins, such as, epoxy resins, phenol resins, polyester resins, and the like, and examples of the organic compound may include aromatic compounds such as divinyl benzene, styrene, ethylvinyl benzene, and the like.

Here, the first polymer of the AP film may be attached onto, for example, a circuit pattern, and the second polymer and the organic compound of the AP film may be mixed and then attached onto the insulating layer or the SR, thereby enhancing the adhesive strength with respect to both layers at the interface between heterogeneous layers.

This AP film may be formed between the circuit pattern and the insulating layer or between the circuit pattern and the solder resist (SR) by a chemical vapor deposition (CVD) method, an initiated chemical vapor deposition (iCVD) method, or a spin coating method.

First, the AP film may be formed between the circuit pattern and the insulating layer or between the circuit pattern and the solder resist (SR) by the spin coating method.

For example, the spin coating method may be performed by dropping an AP solution, in which a mixture of the first polymer or the second polymer and the organic compound is dissolved in a volatile organic solvent such as benzene, toluene, or the like, on a surface of the substrate mounted on a spin coater.

After that, the AP solution may be coated on the overall substrate including the circuit pattern or the insulating layer by a rotary power of the spin coater on which the substrate is mounted.

Then, a hardening treatment is performed on the coated AP solution to thereby volatilize and remove the volatile organic solvent, and thus form an AP film on the substrate including the circuit pattern or the insulating layer.

Second, since the AP film is formed between the circuit pattern and the insulating layer or between the circuit pattern and the SR by using a polymer, the iCVD method is preferably used.

Specifically, according to the iCVD method, as shown in FIG. 1, a monomer M of the polymer constituting the AP film is evaporated to thereby form a polymer thin film P through a gas phase polymerization reaction where a polymerization reaction of the polymer and a film forming process are simultaneously advanced, in a chamber. Through this iCVD method, the monomer M and an initiator I are evaporated to advance a chain polymerization reaction using free radicals R in a gas phase, so that the polymer thin film P can be deposited on the surface of the substrate 200 including the circuit pattern or the insulating layer.

The simple mixing of the initiator I and the monomer M does not lead to the polymerization reaction. However, when the initiator I is decomposed by a high-temperature filament 110 positioned in the iCVD chamber to thereby generate radicals R, the monomer M is activated due to this, and thus the chain polymerization reaction occurs.

As the initiator I, peroxide such as tert-butylperoxide (TBPO) or tert-amyl peroxide (TAPO) may be mainly used. This initiator I is a volatile material having a boiling point of about 110° C., and thermally decomposed at about 150° C.

Therefore, the high-temperature filament 110 used in the iCVD chamber is maintained at about 200˜250° C., the chain polymerization reaction may be easily induced. Here, the temperature of the filament 110 is high enough to thermally decompose the initiator I of peroxide, but most of the organic materials including monomers M used in the iCVD method are not thermally decomposed at such the temperature.

The free radical R formed through decomposition of the initiator I may be transferred to the monomer M, to induce the chain reaction, to thereby form a polymer P. The thus formed polymer P is deposited on the substrate maintained at a low temperature, to thereby form an AP film.

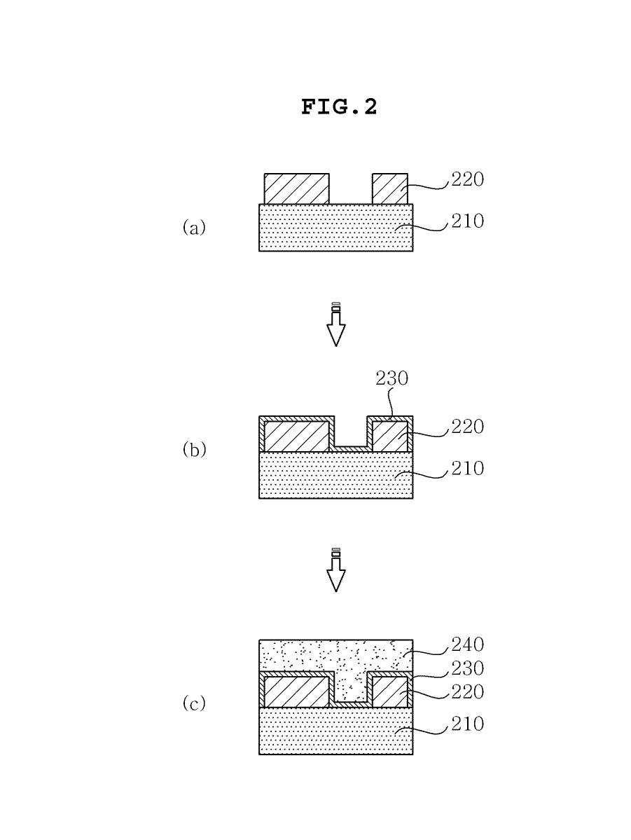

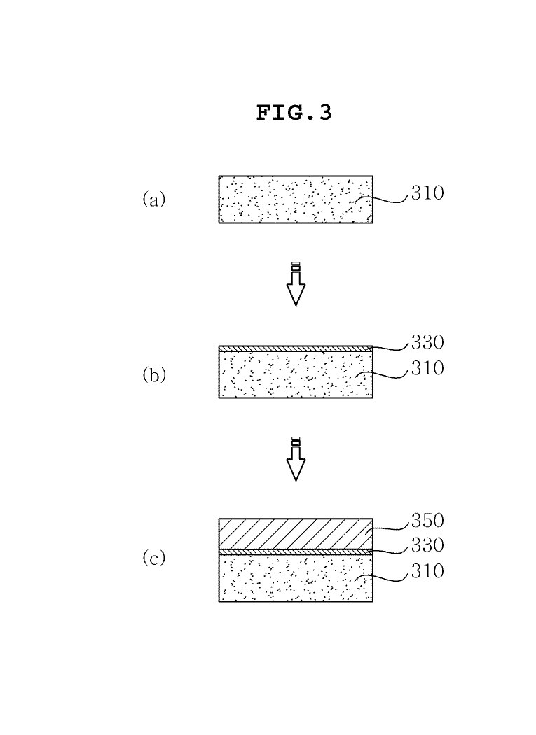

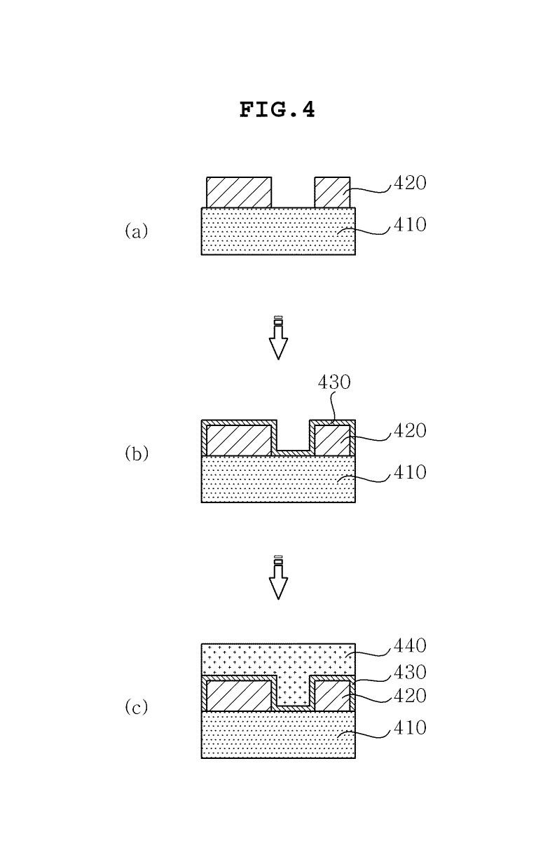

Hereinafter, the methods for manufacturing a printed circuit board including the AP film according to preferred embodiments of the present invention with reference to the accompanying FIGS. 2A to 4C. FIGS. 2A to 2C are process sectional views for illustrating a method for manufacturing a printed circuit board including an AP film according to a first preferred embodiment of the present invention; FIGS. 3A to 3C are process sectional views for illustrating a method for manufacturing a printed circuit board including an AP film according to a second preferred embodiment of the present invention; and FIGS. 4A to 4C are process sectional views for illustrating a method for manufacturing a printed circuit board including an AP film according to a third preferred embodiment of the present invention.

As shown in FIG. 2A, the method for manufacturing a printed circuit board including an AP film according to a first preferred embodiment of the present invention is applied to a state where a circuit pattern 220 is formed on an insulating layer 210 above a substrate.

As shown in FIG. 2B, any one of CVD, iCVD, and spin coating methods is performed on the insulating layer 210 including the circuit pattern 220 to thereby form an AP film 230 having a thickness of 0.01˜1 μm.

Specifically, the AP film 230 is formed of a first polymer or a second polymer and an organic compound. Examples of the first polymer may include any one or a mixture of amine based polymers, imidazole based polymers, and pyridine based polymers; examples of the second polymer may include heat-hardenable synthetic resins, such as, epoxy resins, phenol resins, polyester resins, and the like; and examples of the organic compound may include aromatic compounds such as divinyl benzene, styrene, ethylvinyl benzene, and the like.

Specifically, the AP film 230 may be formed by first attaching the first polymer in a direction of the circuit pattern 220 and forming a film containing the second polymer and the organic compound on the first polymer.

As shown in FIG. 2C, an upper insulating layer 240 is formed on an upper surface of the AP film 230.

The thus formed AP film 230 can enhance the adhesive strength with respect to the circuit pattern 220 by using the first polymer and enhance the adhesive strength with respect to the upper insulating layer 240 by using the second polymer and the organic compound.

Therefore, in the printed circuit board including the AP film 230 according to the first preferred embodiment of the present invention, the adhesive strength with respect to the circuit pattern 220 and the upper insulating layer 240 can be enhanced, resulting in improving the reliability of the printed circuit board.

In addition, as shown in FIG. 3A, the method for manufacturing a printed circuit board including an AP film according to a second preferred embodiment of the present invention is applied to a state where an insulating layer 310 is provided on a substrate.

As shown in FIG. 3B, any one of CVD, iCVD, and spin coating methods is performed on the insulating layer 310 to thereby form an AP film 330.

The AP film 330 contains a first polymer, a second polymer, and an organic compound, as described above. The AP film may be formed to have a thickness of 0.01˜1 μm by using any one of CVD, iCVD, and spin coating methods. Here, the AP film 330 is preferably formed by the iCVD method.

For example, the AP film 330 may be formed by first attaching a film made of the second polymer and the organic compound on an upper surface of the insulating layer 310 and forming a film containing the first polymer on the film made of the second polymer and the organic compound.

As shown in FIG. 3C, after the AP film 330 is formed, a copper plating layer 350 is formed on an upper surface of the AP film 330. Here, the copper plating layer 350 may be formed by, for example, an electroless copper plating method.

The thus formed copper plating layer 350 may be formed into a fine circuit pattern through a patterning process including lithography and etching processes.

Here, the AP film 330 has a low roughness (Ra) value of, for example 0.1 μm and improved adhesive strength with the copper plating layer 350, and thus may contribute to form the copper plating layer 350 into the fine circuit pattern.

Therefore, in the method for manufacturing a printed circuit board according to the second preferred embodiment of the present invention, there can be provided a printed circuit board having a fine circuit pattern by using the AP film 330 having a low roughness value and having improved adhesive strength with the copper plating layer 350.

In addition, as shown in FIG. 4A, in the method for manufacturing a printed circuit board according to a third preferred embodiment of the present invention, an AP film 430 is interposed between a circuit pattern 420 and an SR layer 440, thereby improving the adhesive strength with respect to the circuit pattern 420 and the SR layer 440.

As shown in FIG. 4A, the method for manufacturing a printed circuit board according to the third preferred embodiment of the present invention is applied to a state where a circuit pattern 420 is formed on an insulating layer 410 above a substrate.

As shown in FIG. 4B, any one of CVD, iCVD, and spin coating methods is performed on the insulating layer 410 including the circuit pattern 420 to thereby form an AP film 430 having a thickness of 0.01˜1 μm.

Here, the AP film 430 may be formed by first attaching the first polymer in a direction of the circuit pattern 420 and growing a film containing the second polymer and the organic compound on the first polymer.

As shown in FIG. 2C, an SR layer 440 is formed on an upper surface of the AP film 430.

Here, the AP film 430 can enhance the adhesive strength with respect to the circuit pattern 420 by using the first polymer and enhance the adhesive strength with respect to the SR layer 440 by using the second polymer and the organic polymer.

Therefore, according to the method for manufacturing a printed circuit board according to the third preferred embodiment of the present invention, there can be provided a printed circuit board having improved adhesive strength with respect to the circuit pattern 420 and the SR layer 440 by using the AP film 430.

Hereinafter, characteristics of the printed circuit board including the AP film according to the present invention will be described in detail by the following examples and comparative examples. Here, the following examples and comparative examples are provided merely for exemplifying contents of the present invention, but the scope of the present invention is not limited thereto.

### EXAMPLE 1

In Example 1, based on the structure of the present invention shown in FIG. 3C, an insulating layer 310 made of an interlayer insulating material, an AP film 330, and a copper plating layer 350 were provided.

Here, the AP film 330 was formed to have a thickness of 0.2 μm, by using a 4-vinylpyridine polymer of pyridine based polymers as the first polymer, an epoxy resin as the second polymer, and a divinyl benzene organic compound, through the iCVD method.

### EXAMPLE 2

In Example 2, based on the structure of the present invention shown in FIG. 3C, an insulating layer 310 made of an interlayer insulating material, an AP film 330, and a copper plating layer 350 are provided.

Here, the AP film 330 was formed to have a thickness of 0.2 μm, by using a 4-vinylpyridine polymer of pyridine based polymers as the first polymer and an epoxy resin as the second polymer, through the iCVD method.

Example 2 is different from Example 1 in that the AP film 330 is formed by skipping an organic compound component of divinyl benzene.

### Comparative Example

In the comparative example, there is shown a structure where a copper plating layer 350 was formed on an upper surface of an insulating layer 310 made of an interlayer insulating material without an AP film 330 in FIG. 3C.

The peel strength was measured by using an SAICAS equipment for the structure of each of Example 1, Example 2, and Comparative Example. It can be seen from Table 1 below that Example 1 exhibited the highest peel strength.

TABLE 1

| | Peel strength (N/mm) |
|---|---|
| Example 1 | 0.50 |
| Example 2 | 0.24 |
| Comparative Example | 0.01 |

Hence, in the printed circuit board according to the present invention, the AP film 330 is used to thereby enhance the adhesive strength between the insulating layer 310 and the copper plating layer 350 for forming a circuit pattern, and thus, the adhesive strength between the circuit pattern and the insulating layer or between the circuit pattern and the SR layer can be enhanced through the AP film 330 even without a separate process for a roughness treatment.

As set forth above, with the printed circuit board including the AP film according to the present invention, the adhesive strength with respect to the circuit pattern and the insulating layer can be enhanced, resulting in improving reliability of the printed circuit board.

According to the method for manufacturing a printed circuit board, a printed circuit board having a fine circuit pattern can be provided by using the AP film having a low roughness value and enhanced adhesive strength with respect to the circuit pattern.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising an adhesion promoter (AP) film for enhancing adhesive strength, interposed between a circuit pattern and an insulating layer above a substrate.

2. The printed circuit board as set forth in claim 1, wherein the AP film contains a first polymer and an organic compound, and the insulating layer includes a solder resist (SR) layer.

3. The printed circuit board as set forth in claim 1, wherein the AP film further contains a second polymer.

4. The printed circuit board as set forth in claim 2, wherein the first polymer includes any one or at least two polymers of amine based polymers, imidazole based polymers, and pyridine based polymers.

5. The printed circuit board as set forth in claim 3, wherein the second polymer includes a heat hardenable synthetic resin.

6. The printed circuit board as set forth in claim 2, wherein the organic compound includes any one or at least two compounds of aromatic compounds.

7. The printed circuit board as set forth in claim 6, wherein the aromatic compounds include divinyl benzene, styrene, and ethylvinyl benzene.

8. The printed circuit board as set forth in claim 2, wherein the AP film is formed by attaching the first polymer onto the circuit pattern and attaching the second polymer and the organic compound onto the insulating layer, by using any one of chemical vapor deposition (CVD), initiated chemical vapor deposition (iCVD), and spin coating methods.

9. A method for manufacturing a printed circuit board, the method comprising forming an AP film for enhancing adhesive strength to be interposed between a circuit pattern and an insulating layer above a substrate.

10. The method as set forth in claim 9, wherein the forming of the AP film includes:
forming an insulating layer above the substrate;
forming the circuit pattern on the insulating layer;
forming the AP film on the insulating layer having the circuit pattern formed thereon; and
forming a different insulating layer on the AP film.

11. The method as set forth in claim 10, wherein the different insulating layer includes a solder resist (SR) layer.

12. The method as set forth in claim 9, wherein the forming of the AP film includes:
forming the insulating layer above the substrate;
forming the AP film on the insulating layer;
forming a copper plating layer on the AP film; and
performing a patterning process for forming the copper plating layer into a circuit pattern.

13. The method as set forth in claim 9, wherein the AP film is formed as a film containing at least one of a first polymer, a second polymer, and an organic compound, by using any one of chemical vapor deposition (CVD), initiated chemical vapor deposition (iCVD), and spin coating methods.

14. The method as set forth in claim 13, wherein the first polymer is attached onto the circuit pattern and the second polymer and the organic compound are attached onto the insulating layer.

15. The method as set forth in claim 13, wherein the first polymer includes any one or at least two polymers of amine based polymers, imidazole based polymers, and pyridine based polymers; the second polymer includes a heat hardenable synthetic resin; and the organic compound includes any one or at least two compounds of aromatic compounds.

16. The method as set forth in claim 15, wherein the aromatic compounds include divinyl benzene, styrene, and ethylvinyl benzene.
